(19) United States
(12) Patent Application Publication
(10) Pub. No.: US 2025/0151297 A1
(43) Pub. Date: May 8, 2025

(54) METHOD OF FORMING PN HETEROJUNCTION BETWEEN NICKEL OXIDE AND GALLIUM OXIDE AND SCHOTTKY DIODE MANUFACTURED BY THE METHOD

(71) Applicant: POWER CUBESEMI INC., Seongnam-si, Gyeonggi-do (KR)

(72) Inventors: Tai Young KANG, Gwangju-si (KR); Sin Su KYOUNG, Hanam-si (KR); Tae Jin NAM, Seongnam-si (KR); Yu Sup JUNG, Suwon-si (KR)

(73) Assignee: POWER CUBESEMI INC., Seongnam-si, Gyeonggi-do (KR)

(21) Appl. No.: 18/721,102

(22) PCT Filed: Dec. 16, 2022
(86) PCT No.: PCT/KR2022/020606

§ 371 Date: Jan. 13, 2025

(30) Foreign Application Priority Data
Dec. 16, 2021 (KR) 10-2021-0180501
Dec. 15, 2022 (KR) 10-2022-0175804

(51) Int. Cl. H10D 8/01; H01L 21/02; H10D 8/60; H10D 62/82

(52) U.S. Cl. CPC H10D 8/051; H01L 21/02631; H10D 62/8271; H10D 8/60

(57) ABSTRACT

Method of forming pn heterojunction between nickel oxide and gallium oxide disclosed. The method includes forming a trench by etching an n-type gallium oxide epitaxial layer epitaxially grown on an n-type gallium oxide substrate using an etch mask, forming a p-type nickel oxide region on the bottom of the trench by sputtering a nickel oxide target on the n-type gallium oxide epitaxial layer in a mixed gas atmosphere of argon and oxygen, and forming a nickel layer on the p-type nickel oxide region by sputtering a nickel target on the n-type gallium oxide epitaxial layer in an argon gas atmosphere.

### CROSS-REFERENCE TO RELATED APPLICATIONS

This application is a national phase entry under 35 USC 371 of International Patent Application No. PCT/KR2022/020606, filed on Dec. 16, 2022, which claims priority to Korean Patent Applications No. 10-2021-0180501, filed on Dec. 16, 2021 and No. 10-2022-0175804, filed on Dec. 15, 2022, which are incorporated herein by reference in their entirety.

### BACKGROUND

The present invention relates to a heterojunction between nickel oxide and gallium oxide.

Due to the rapid developments of the power, automotive electronics and home appliance industries, the demand for high-performance power semiconductor devices has exploded. Due to ongoing research, ultra-wideband semiconductors including silicon carbide and gallium nitride have achieved higher performance than silicon-based power semiconductors. However, they have the disadvantages of difficult bulk single crystal growth and high production costs.

Gallium oxide is an emerging ultra-wideband semiconductor material after silicon carbide and gallium nitride, with a bandgap of about 4.7 to about 4.9 eV, far beyond the bandgap width of silicon carbide and gallium nitride, and a theoretical breakdown field of 8 MV/cm. Gallium oxide is particularly capable of growing substrates and epitaxial layers at relatively low cost compared to other ultra-wideband semiconductor materials. However, because the effective hole mass of an appropriate p-type dopant is large and the acceptor activation energy is high, it is difficult to implement a pn homojunction-based β-Ga₂O₃ device.

### SUMMARY

According to one aspect of the present invention, there is provided a method of forming NiO—Ga₂O₃ heterojunction. The method may include forming a trench by etching an n-type gallium oxide epitaxial layer epitaxially grown on an n-type gallium oxide substrate using an etch mask, forming a p-type nickel oxide region on the bottom of the trench by sputtering a nickel oxide target on the n-type gallium oxide epitaxial layer in a mixed gas atmosphere of argon and oxygen, and forming a nickel layer on the p-type nickel oxide region by sputtering a nickel target on the n-type gallium oxide epitaxial layer in an argon gas atmosphere.

In one embodiment, the etch mask may be composed of a hard mask on the n-type gallium oxide epitaxial layer and a photoresist mask formed on the hard mask,

In one embodiment, the etch mask may form a sidewall slope of the trench in the range of 45 degrees to 70 degrees.

In one embodiment, the photoresist mask forms a first trench region in the n-type gallium oxide epitaxial layer, and the hard mask forms a second trench region having sidewalls extending from sidewalls of the first trench region.

In one embodiment, an oxygen flow ratio in the mixed gas is in a range of 9.0% and 23.0%.

In one embodiment, the oxygen flow ratio in the mixed gas is in a range of 16.6% and 23.0%.

According to another aspect of the present invention, there is provided a method of manufacturing a nickel oxide-gallium oxide heterojunction diode including forming a plurality of trenches in an active area and an edge area by etching an n-type gallium oxide epitaxial layer epitaxially grown on an n-type gallium oxide substrate using an etch mask, forming a p-type nickel oxide region on the bottom of the plurality of trenches by sputtering a nickel oxide target on the n-type gallium oxide epitaxial layer in a mixed gas atmosphere of argon and oxygen, forming an insulating layer that defines the active area in the edge area, forming a nickel layer on the p-type nickel oxide region and the n-type gallium oxide epitaxial layer by sputtering a nickel target in the active region and the edge region in an argon gas atmosphere, and forming an anode electrode on an upper surface of the nickel layer and a cathode electrode on a lower surface of the n-type gallium oxide substrate.

In one embodiment, the p-type nickel oxide region may include a first p-type nickel oxide region formed in the active area, a second p-type nickel oxide region formed across the active area and the edge area, and a third p-type nickel oxide region formed in the edge area.

### BRIEF DESCRIPTION OF DRAWINGS

Hereinafter, embodiments of the invention will be described with reference to the accompanying drawings. For the purpose of easy understanding of the invention, the same elements will be referred to by the same reference signs. Configurations illustrated in the drawings are examples for describing the invention, and do not restrict the scope of the invention. Particularly, in the drawings, some elements are slightly exaggerated for the purpose of easy understanding of the invention. Since the drawings are used to easily understand the invention, it should be noted that widths, depths, and the like of elements illustrated in the drawings might change at the time of actual implementation thereof. Meanwhile, throughout the detailed description of the invention, the same components are described with reference to the same reference numerals.

FIG. 1 exemplarily illustrates a nickel oxide-gallium oxide pn heterojunction Schottky diode;

FIG. 2 exemplarily illustrates the process of forming a hard mask pattern to form the nickel oxide-gallium oxide pn heterojunction;

FIG. 3 exemplarily illustrates the process of forming the nickel oxide-gallium oxide pn heterojunction on the gallium oxide epitaxial layer in still another embodiment;

FIG. 4 is an enlarged view of A of FIG. 3, exemplarily illustrating a process for adjusting the slope of the sidewalls of a trench;

FIG. 5 and FIG. 6 exemplarily illustrate the process for fabricating a nickel oxide-gallium oxide pn heterojunction Schottky diode.

FIG. 7 is a graph illustrating an electrical characterization of nickel oxide as a function of oxygen flow ratio;

FIG. 8 is a graph illustrating a current density measured by applying a forward voltage to a nickel oxide-gallium oxide pn heterojunction Schottky diode; and

FIG. 9 is a graph illustrating a current density measured by applying a reverse voltage to a nickel oxide-gallium oxide pn heterojunction Schottky diode.

### DETAILED DESCRIPTION

Embodiments which will be described below with reference to the accompanying drawings can be implemented singly or in combination with other embodiments. But this is not intended to limit the present invention to a certain embodiment, and it should be understood that all changes, modifications, equivalents or replacements within the spirits and scope of the present invention are included. Especially, any of functions, features, and/or embodiments can be implemented independently or jointly with other embodiments. Accordingly, it should be noted that the scope of the invention is not limited to the embodiments illustrated in the accompanying drawings.

Terms such as first, second, etc., may be used to refer to various elements, but, these element should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings.

Hereinafter, embodiments of the present invention will be described in detail with reference to the accompanying drawings.

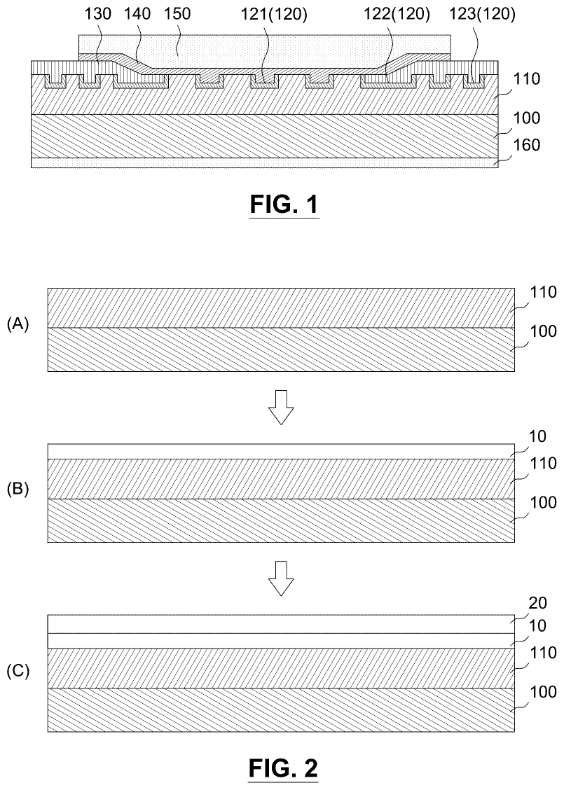

FIG. 1 exemplarily illustrates a nickel oxide-gallium oxide pn heterojunction Schottky diode.

Referring to FIG. 1, the nickel oxide-gallium oxide pn heterojunction Schottky diode includes an n-type gallium oxide substrate 100, an n-type gallium oxide epitaxial layer 110, and a p-type nickel oxide region 121, 122, 123 (collectively referred to as 120), an insulating layer 130, a Schottky metal layer 140, an anode electrode 150, and a cathode electrode 160.

The n-type gallium oxide substrate 100 may be formed of single crystalline β-gallium oxide (β-Ga₂O₃) doped with an n-type dopant. The thickness of the n-type gallium oxide substrate 100 may be about 590 μm, and the n-type dopant concentration may be about 4E18 cm⁻³. The n-type dopant may be, for example, tin (Sn).

The n-type gallium oxide epitaxial layer 110 may be undoped or n-type doped β-gallium oxide epitaxially grown on the main surface of the n-type gallium oxide substrate 100. The n-type dopant may be, for example, silicon (Si), and the concentration of the n-type dopant may be about 1E16 cm⁻³. The thickness of the n-type gallium oxide epitaxial layer 110 may be about 10 μm.

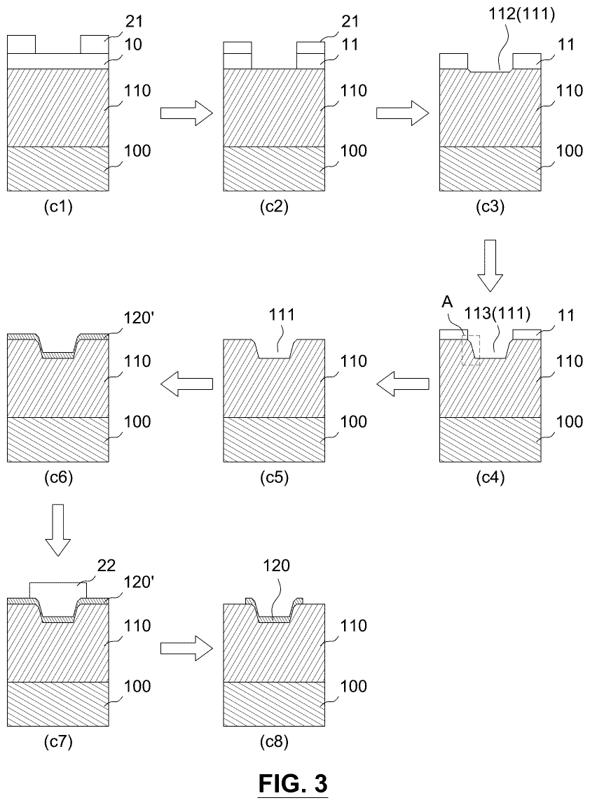

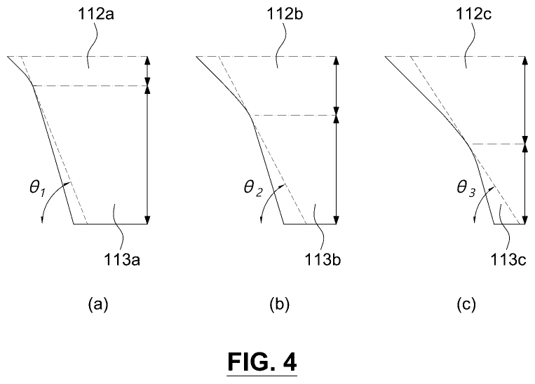

The p-type nickel oxide (NiOx) region 120 is formed on the bottom surface of the trench (see 111 in FIGS. 3 and 112 in FIG. 4) extending inward from the upper surface of the n-type gallium oxide epitaxial layer 110, and depending on the slope of the side wall of the trench, it may also be formed on the side wall. The p-type nickel oxide region 120 includes a plurality of first p-type nickel oxide regions 121 formed in the active area of the Schottky diode, a second p-type nickel oxide region 122 formed to surround the active area, and a plurality of third p-type nickel oxide regions 123 formed in the edge area. The plurality of first p-type nickel oxide regions 121 serve as a junction barrier, the second p-type nickel oxide region 122 serves as a buffer, and the plurality of third p-type nickel oxide regions 121 serve as an electric field limiting structure, for example, a guard ring. Here, one side of the second p-type nickel oxide region 122 may contact the Schottky metal layer 130. The p-type nickel oxide region 120 may be formed through a sputtering process. The p-type nickel oxide region 120 and the n-type gallium oxide epitaxial layer 110 form a pn heterojunction.

The insulating layer 130 is formed on at least a portion of the second p-type nickel oxide region 122 and on the edge area to define the active area. The insulating layer 130 fills the inside of the trench in which the second p-type nickel oxide region 122 is formed and the trench in which the third p-type nickel oxide regions 123 are formed. Therefore, at least a portion of the lower surface of the insulating layer 130 is in contact with the second p-type nickel oxide region 122 and the third p-type nickel oxide region 123, and the remaining region is in contact with the upper surface of the n-type gallium oxide epitaxial layer 110. The inner surface of the insulating layer 130 may be formed with a downward slope towards the active area. When viewed from above, the sloped surface may overlap with at least a portion of the second p-type nickel oxide region 122.

The Schottky metal layer 140 is formed on the n-type gallium oxide epitaxial layer 110 in the active area so as to contact the upper surface of the n-type gallium oxide epitaxial layer 110 and the plurality of first p-type nickel oxide regions 121. The Schottky metal layer 140 and the upper surface of the n-type gallium oxide epitaxial layer 110 is in Schottky contact, and the Schottky metal layer 140 and the plurality of first p-type nickel oxide regions 121 are in ohmic contact. The Schottky metal layer 140 may extend laterally to cover a portion of the insulating layer 130.

The anode electrode 150 is formed on the upper surface of the Schottky metal layer 140, and the cathode electrode 160 is formed on the lower surface of the n-type gallium oxide substrate 100. A silicide layer (not shown) for ohmic contact may be formed between the n-type gallium oxide substrate 100 and the cathode electrode 160.

Hereinafter, the operation of the nickel oxide-gallium oxide pn heterojunction Schottky diode having the plurality of p-type nickel oxide regions 120 will be described.

The plurality of first p-type nickel oxide regions 121 form a pn heterojunction with the n-type gallium oxide epitaxial layer 110, so that breakdown voltage and leakage current characteristics can be improved compared to a conventional Schottky diode. When a reverse voltage is applied, the plurality of first p-type nickel oxide regions 121 form a depletion layer due to pn junction with the n-type gallium oxide epitaxial layer 110. Since the depletion layer formed along the periphery of the plurality of first p-type nickel oxide regions 121 blocks the path through which leakage current can flow, it has a lower leakage current value than a typical Schottky diode. In particular, the depletion layer formed along the periphery of the plurality of first p-type nickel oxide regions 121 can relatively reduce the electric field concentrated in the area where the Schottky metal layer 140 and the n-type gallium oxide epitaxial layer 110 are in contact. As a result, a relatively higher threshold voltage than a typical Schottky diode can be realized.

FIG. 2 exemplarily illustrates the process of forming a hard mask pattern to form the nickel oxide-gallium oxide pn heterojunction.

In (A), the n-type gallium oxide epitaxial layer 110 is formed on the main surface of the n-type gallium oxide substrate 100. The n-type gallium oxide substrate 100 is cleaned and plasma treated to remove foreign substances. The n-type gallium oxide epitaxial layer 110 may be undoped or n-type doped β-gallium oxide epitaxially grown on the main surface of the n-type gallium oxide substrate 100. The n-type dopant may be, for example, silicon (Si), and the concentration of the n-type dopant may be about 1E16 cm⁻³. The thickness of the n-type gallium oxide epitaxial layer 110 may be about 10 μm. The n-type gallium oxide epitaxial layer 110 may be deposited on the n-type gallium oxide substrate 100 by, for example, halide vapor phase epitaxy (HVPE), metalorganic chemical vapor deposition (MOCVD), Mist CVD, molecular beam epitaxy (MBE), pulsed laser deposition (PLD), and so on.

In (B), a silicon oxide layer 10 is formed on the upper surface of the n-type gallium oxide epitaxial layer 110. The silicon oxide layer 10 may be formed by depositing silicon oxide (SiO₂) to a thickness of about 0.7 μm by chemical vapor deposition or spin coating.

In (C), a photoresist layer 20 is formed to a thickness of about 1.6 μm on the upper surface of the silicon oxide layer 10. The photoresist layer 20 may be formed by spin coating the photoresist on the silicon oxide layer 10 and then soft baking it.

FIG. 3 exemplarily illustrates the process of forming the nickel oxide-gallium oxide pn heterojunction on the gallium oxide epitaxial layer in still another embodiment. After the process illustrated in FIG. 2, the n-type gallium oxide epitaxial layer 110 may be etched using a hard mask and a photoresist mask as an etch mask to form a trench 111 and the p-type nickel oxide region 120 on at least a bottom surface of the trench 111.

In (c1), the photoresist mask 21 is formed by removing the photoresist in the region where the trench 111 is to be formed from the photoresist layer 20.

In (c2), the hard mask 11 is formed by etching the silicon oxide layer 10 exposed by the photoresist mask 21.

In (c3), a first trench region 112 is formed by etching the n-type gallium oxide epitaxial layer 110 exposed by the hard mask 11 and the photoresist mask 21 on the hard mask 11. The first trench region 112 may be formed by the photoresist mask 21. Since the photoresist mask 21 is also etched at a constant rate, the thickness of the photoresist mask 21 can be adjusted according to the depth of the first trench region 112.

In (c4), a second trench region 113 having sidewalls extending from the sidewalls of the first trench region 112 is formed using the hard mask 11. The first trench region 112 and the second trench region 113 form the trench 111.

In (c5), the hard mask 11 is removed.

In (c6), a p-type nickel oxide layer 120′ is formed in the trench 111. In a mixed gas atmosphere of argon and oxygen, the p-type nickel oxide layer 120′ is deposited to a thickness of about 300 nm in the trench 111 and on the upper surface of the n-type gallium oxide epitaxial layer 110 by sputtering a nickel oxide target or a nickel target. During sputtering, the flow rate of oxygen may be adjusted between about 0.0% and 23.0%, preferably between about 9.0% and 16.6%, the chamber pressure may be maintained at about 5 m Torr, and a power of about 150 W may be applied for about 90 minutes.

In (c7), the photoresist mask 22 is formed in the trench 111 in which the p-type nickel oxide layer 120′ is formed, and the p-type nickel oxide layer 120′ deposited on the upper surface of the n-type gallium oxide epitaxial layer 110 is removed by etching.

In (c8), the photoresist mask 22 is removed.

FIG. 4 is an enlarged view of A of FIG. 3, exemplarily illustrating a process for adjusting the slope of the sidewalls of a trench.

The sidewall slope from the entrance to the bottom of the first trench region 112 is determined by the thickness of the photoresist mask 21, and the sidewall slope of the second trench region 113 is determined by a combination of the sidewall slope of the first trench region 112 and the hard mask 11. Thus, using the hard mask 11 and the photoresist mask 21 as the etch mask, the sidewall slope of the trench 111 may be adjusted between about 45 degrees and about 70 degrees.
(a), (b), and (c) of FIG. 4 illustrate the trench sidewall slope when the thickness of the photoresist mask 21 is increased while maintaining the sum of the thickness of the photoresist mask 21 and the thickness of the hard mask 11. The first trench regions 112a, 112b, 112c formed by the photoresist mask 21 have sidewalls sloped at approximately 45 degrees due to the polymer created by the photoresist. As the thickness of the photoresist increases, the depth of the first trench regions 112a, 112b, 112c becomes deeper, and the depth of the second trench regions 113a, 113b, 113c becomes inversely shallower. When the etching by the photoresist mask 21 is completed, the etching by the hard mask 11 begins. During the etching process by the hard mask, the sidewalls, which are inclined at about 45 degrees due to the polymer, are also etched downward. This may cause the sidewalls of the trench 111 to be close to a curved surface overall, so that the sidewall slopes θ1, θ2, and θ3 can be measured using a tangent line touching the curved surface. The sidewall slope θ1 in the case of the thinnest photoresist mask 21 approaches about 70 degrees, and the sidewall slope θ3 in the case of the thinnest hard mask 11 approaches about 45 degrees.

Meanwhile, the depth of the trench 111 composed of the first trench region 112 and the second trench region 113 may also be adjusted. As a result, the entrance edge and the bottom edge of the trench 111 are formed at an obtuse angle, which reduces the electric field concentration at the entrance edge and the bottom edge, and the depth of the p-type nickel oxide region 120, that is, the vertical distance from the upper surface of the n-type gallium oxide epitaxial layer 110 to the p-type nickel oxide region 120 can be adjusted.

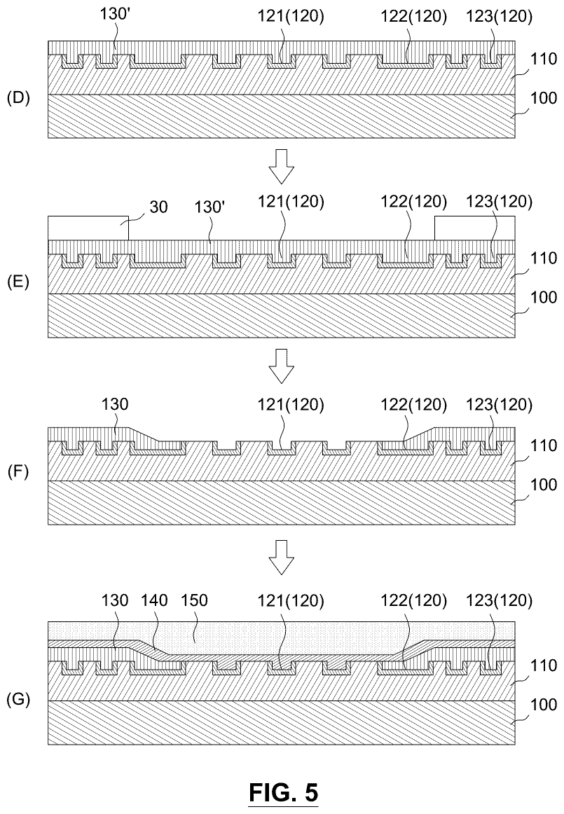

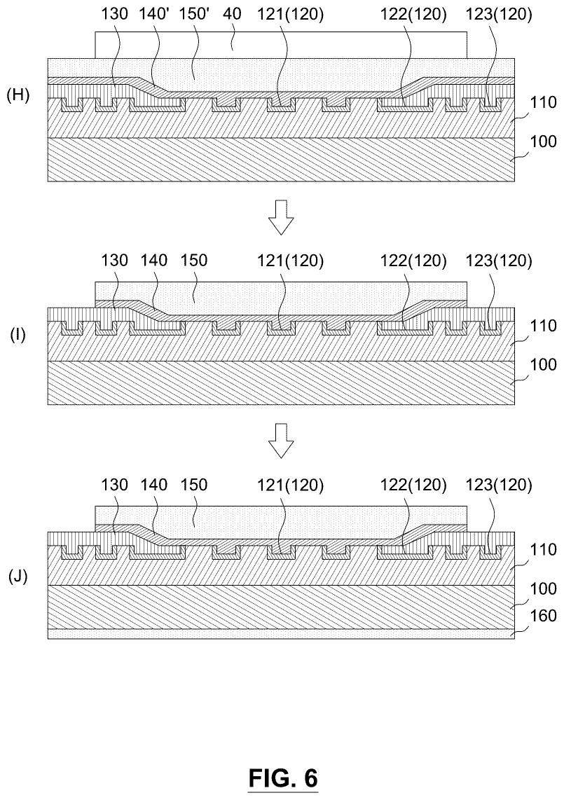

FIG. 5 and FIG. 6 exemplarily illustrate the process for fabricating a nickel oxide-gallium oxide pn heterojunction Schottky diode.

In (D), after the nickel oxide-gallium oxide pn heterojunction formation process illustrated in FIGS. 3 to 4 is completed, an insulating material layer 130′ is formed on the entire upper surface of the n-type gallium oxide epitaxial layer 110. The insulating material layer 130′ may be formed by depositing, for example, silicon oxide (SiO₂), phosphosilicate glass (PSG), borosilicate glass (BSG), or borophosphosilicate glass (BPSG).

In (E), a photoresist mask 30 is formed on the upper surface of the insulating material layer 130′. The photoresist mask 30 defines an etch area in the insulating material layer 130′.

In (F), the insulating material layer 130′ is etched to form the insulating layer 130, and the photoresist layer 30 is removed. The insulating layer 130 may be formed by etching the insulating material layer 130′ with a downwardly sloping side facing the active region of the insulating material layer 130′.

In (G), a Schottky metal layer 140 is formed on the n-type gallium oxide epitaxial layer 110 in the active area and the insulating layer 130. In an argon atmosphere, the Schottky metal layer 140 may be deposited to a thickness of about 100 nm on the n-type gallium oxide epitaxial layer 110 and the insulating layer 130 by sputtering a nickel target. During sputtering, the flow rate of argon may be maintained at about 20 sccm, the chamber pressure may be maintained at about 5 mTorr, and a power of about 100 W may be applied for about 8 minutes.

The anode electrode 150 is formed on the Schottky metal layer 140. The anode electrode 150 may be formed of metal (Ti, Au, Al) or metal alloy.

In (H), a photoresist layer 40 is formed on the anode electrode 150. When viewed from above, the photoresist layer 40 may extend laterally to overlap the third p-type nickel oxide region 123 formed at the innermost region of the edge area.

In (I), the Schottky metal layer 140 and the anode metal layer 150 on which the photoresist layer 40 is not formed are removed.

In (J), the cathode electrode 160 is formed on the lower surface of the n-type gallium oxide substrate 100. The cathode electrode 160 may be formed of metal (Ti, Au, Al) or metal alloy.

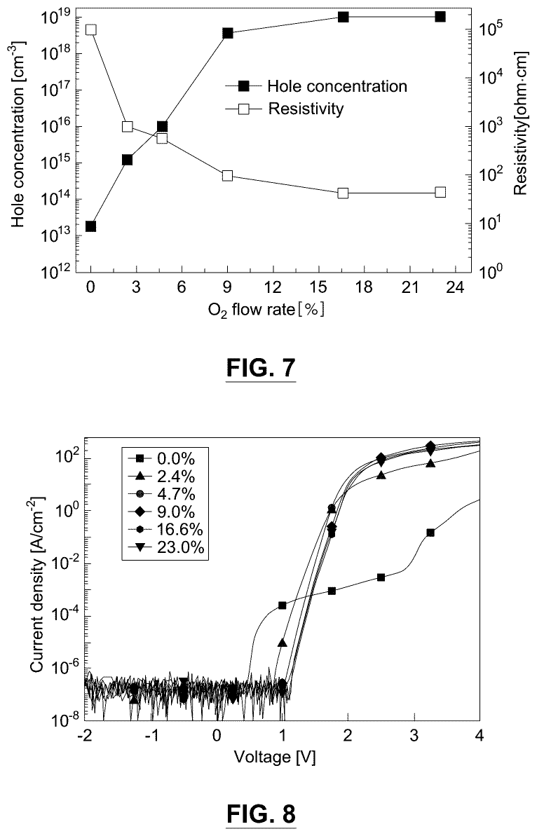

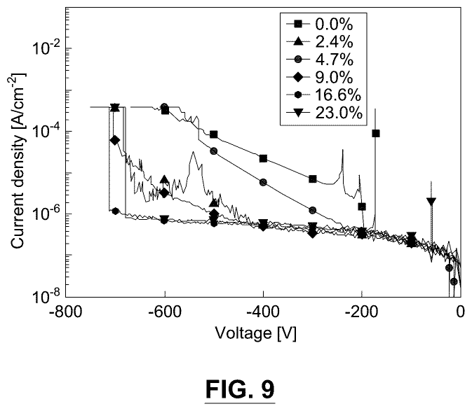

FIG. 7 is a graph illustrating an electrical characterization of nickel oxide as a function of oxygen flow ratio, FIG. 8 is a graph illustrating a current density measured by applying a forward voltage to a nickel oxide-gallium oxide pn heterojunction Schottky diode, and FIG. 9 is a graph illustrating a current density measured by applying a reverse voltage to a nickel oxide-gallium oxide pn heterojunction Schottky diode.

Hole concentration and resistivity of the p-type nickel oxide layer 120′ may be adjusted with the oxygen flow ratio during deposition. FIG. 9 shows the hole concentration and resistivity of the p-type nickel oxide layer 120′ deposited while adjusting the oxygen flow ratio to about 0.0%, about 2.4%, about 4.7%, about 9.0%, about 16.6%, and about 23.0% in an argon-oxygen mixed gas, and Table 1 shows the process parameters and measured breakdown voltage for each oxygen flow ratio.

TABLE 1

| | Oxygen flow ratio | | | | | |
|---|---|---|---|---|---|---|
| | 0.0% | 2.4% | 4.7% | 9.0% | 16.6% | 23.0% |
| Process time | 37 | 66 | 85 | 89 | 90 | 92 |
| (min.) | | | | | | |
| Deposition | 8.1 | 4.5 | 3.5 | 3.4 | 3.3 | 3.2 |
| rate | | | | | | |
| (nm/min) | | | | | | |
| Hole | 1.8 × 10¹³ | 1.2 × 10¹⁵ | 1.0 × 10¹⁶ | 3.7 × 10¹⁸ | 1.05 × 10¹⁹ | 1.03 × 10¹⁹ |
| concentration | | | | | | |
| (cm⁻³) | | | | | | |
| Resistivity | 98,400 | 994 | 564 | 96 | 42 | 44 |
| (ohm · cm) | | | | | | |
| Breakdown | 623 | 683 | 570 | 705 | 713 | 678 |
| voltage | | | | | | |
| (V) | | | | | | |

Referring to FIGS. 7 though 9 together, as the oxygen flow ratio increases, the Hall concentration increases, while the resistivity decreases. The Hall concentration in the oxygen flow ratio range of about 9.0% to about 23.0% is significantly greater than the Hall concentration in the oxygen flow ratio range of about 0.0% to about 4.7%, and the resistivity in the range of about 16.6% to about 23.0% oxygen flow ratio is significantly less than the resistivity in the oxygen flow ratio range of about 0.0% to about 9.0%. Meanwhile, the breakdown voltage is the largest in the oxygen flow ratio range of about 9.0% to about 23.0%. Therefore, the oxygen flow ratio may be adjusted in the range of about 9.0% to about 23.0%, and preferably in the range of about 16.6% to about 23.0%. Referring to FIG. 8, it can be seen that the forward voltage-current characteristics of the nickel oxide-gallium oxide pn heterojunction Schottky diode manufactured with the oxygen flow ratio of about 2.4% to about 23.0% are almost similar, and the turn-on voltage is about 2.0 V or less. On the other hand, the forward voltage-current characteristics of the nickel oxide-gallium oxide pn heterojunction Schottky diode without oxygen (oxygen flow ratio=0.0%) are bumped and have a turn-on voltage close to about 4 V. Referring to FIG. 9, the reverse voltage-current characteristic of the nickel oxide-gallium oxide pn heterojunction Schottky diode manufactured with an oxygen flow ratio of about 9.0% to about 16.6% has a breakdown voltage of about 700 V or more, whereas the nickel oxide-gallium oxide pn heterojunction Schottky diode manufactured with an oxygen flow ratio of about 0.0% to about 4.7% has a breakdown voltage of 700 V or less. Meanwhile, it can be seen that the leakage current of the nickel oxide-gallium oxide pn heterojunction Schottky diode manufactured with an oxygen flow ratio of about 16.6% to about 23.0% remains constant until just before the breakdown voltage, while the leakage current of the nickel oxide-gallium oxide p-n heterojunction Schottky diode manufactured with other oxygen flow ratios increases steadily.

The above description of the invention is exemplary, and those skilled in the art can understand that the invention can be modified in other forms without changing the technical concept or the essential feature of the invention. Therefore, it should be understood that the above-mentioned embodiments are exemplary in all respects, but are not definitive.

The scope of the invention is defined by the appended claims, not by the above detailed description, and it should be construed that all changes or modifications derived from the meanings and scope of the claims and equivalent concepts thereof are included in the scope of the invention.

What is claimed is:

1. A method of forming NiO—Ga₂O₃ heterojunction, comprising:
forming a trench by etching an n-type gallium oxide epitaxial layer epitaxially grown on an n-type gallium oxide substrate using an etch mask;
forming a p-type nickel oxide region on the bottom of the trench by sputtering a nickel oxide target on the n-type gallium oxide epitaxial layer in a mixed gas atmosphere of argon and oxygen; and
forming a nickel layer on the p-type nickel oxide region by sputtering a nickel target on the n-type gallium oxide epitaxial layer in an argon gas atmosphere.

2. Method of claim 1, wherein the etch mask is composed of a hard mask on the n-type gallium oxide epitaxial layer and a photoresist mask formed on the hard mask,
wherein the etch mask forms a sidewall slope of the trench in the range of 45 degrees to 70 degrees.

3. The method of claim 2, wherein the photoresist mask forms a first trench region in the n-type gallium oxide epitaxial layer, and the hard mask forms a second trench region having sidewalls extending from sidewalls of the first trench region.

4. The method of claim 1, wherein an oxygen flow ratio in the mixed gas is in a range of 9.0% and 23.0%.

5. The method of claim 4, wherein the oxygen flow ratio in the mixed gas is in a range of 16.6% and 23.0%.

6. A method of manufacturing a nickel oxide-gallium oxide heterojunction diode comprising:
forming a plurality of trenches in an active area and an edge area by etching an n-type gallium oxide epitaxial layer epitaxially grown on an n-type gallium oxide substrate using an etch mask;
forming a p-type nickel oxide region on the bottom of the plurality of trenches by sputtering a nickel oxide target on the n-type gallium oxide epitaxial layer in a mixed gas atmosphere of argon and oxygen;
forming an insulating layer that defines the active area in the edge area;
forming a nickel layer on the p-type nickel oxide region and the n-type gallium oxide epitaxial layer by sputtering a nickel target in the active region and the edge region in an argon gas atmosphere; and
forming an anode electrode on an upper surface of the nickel layer and a cathode electrode on a lower surface of the n-type gallium oxide substrate.

7. The method of claim 6, wherein the etch mask is composed of a hard mask on the n-type gallium oxide epitaxial layer and a photoresist mask formed on the hard mask,
wherein the etch mask forms a sidewall slope of the trench in the range of 45 degrees to 70 degrees.

8. The method of claim 7, wherein the photoresist mask forms a first trench region in the n-type gallium oxide epitaxial layer, and the hard mask forms a second trench region having sidewalls extending from sidewalls of the first trench region.

9. The method of claim 6, wherein an oxygen flow ratio in the mixed gas is in a range of 9.0% and 23.0%.

10. The method of claim 9, wherein the oxygen flow ratio in the mixed gas is in a range of 16.6% and 23.0%.

11. The method of claim 6, wherein the p-type nickel oxide region comprises:
a first p-type nickel oxide region formed in the active area;
a second p-type nickel oxide region formed across the active area and the edge area; and
a third p-type nickel oxide region formed in the edge area.
